(19) United States
(12) Patent Application Publication
(10) Pub. No.: US 2010/0136796 A1
(43) Pub. Date: Jun. 3, 2010

(54) SUBSTRATE HOLDING MEMBER, IMMERSION TYPE EXPOSURE DEVICE AND METHOD OF FABRICATING SEMICONDUCTOR DEVICE

(76) Inventors: Masayuki HATANO, Kanagawa (JP); Takuya KONO, Kanagawa (JP); Yasutada NAKAGAWA, Kanagawa (JP); Yuji SASAKI, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/628,800

(22) Filed: Dec. 1, 2009

(30) Foreign Application Priority Data
Dec. 2, 2008 (JP) 2008-307866

(51) Int. Cl. H01L 21/30; G03B 27/58

(52) U.S. Cl. 438/758; 355/72; 257/E21.211

(57) ABSTRACT

A substrate holding member according to an embodiment includes an opening having a minimum internal diameter lager than a diameter of a space in which a substrate to be exposed on a substrate stage is disposed, wherein an inner peripheral surface of the opening has a shape expanding toward a lower surface at least partly.

### CROSS-REFERENCE TO RELATED APPLICATIONS

This application is based upon and claims the benefit of priority from prior Japanese Patent Application No. 2008-307866, filed on Dec. 2, 2008, the entire contents of which are incorporated herein by reference.

### BACKGROUND

In accordance with reduction in pattern dimension and high integration of a semiconductor device, an immersion type exposure device capable of broadening numerical apertures NA and focal depth is proposed. This technique is disclosed, for example, in JP-A-2006-202825.

The immersion type exposure device is operable to dispose a wafer on a wafer stage, dispose a substrate jig for holding the wafer around the wafer, form an immersion area between a projection lens and the wafer locally, allow the immersion area to move relatively to the wafer and simultaneously, expose the wafer via the immersion area. The substrate jig has an opening in which the wafer is disposed, and at least the upper side of the inner peripheral surface of the opening is constructed from a curved surface bulging toward an opposite side to the opening in accordance with a side shape of the wafer.

### BRIEF SUMMARY

A substrate holding member according to an embodiment includes an opening having a minimum internal diameter lager than a diameter of a space in which a substrate to be exposed on a substrate stage is disposed, wherein an inner peripheral surface of the opening has a shape expanding toward a lower surface at least partly.

An immersion exposure device according to another embodiment includes a substrate holding member having an opening inside which a substrate to be exposed is disposed, wherein an inner peripheral surface of the opening has a shape expanding toward a lower surface at least partly, a substrate stage on which the substrate holding member is disposed, and a controller for allowing an immersion area interposed between an end part of projection optics and the substrate to be exposed to move relatively to the substrate to be exposed and simultaneously, exposing emission areas of the substrate to be exposed covered with the immersion area.

A method of fabricating a semiconductor device according to another embodiment includes disposing a substrate holding member on a substrate stage, the substrate holding member having an opening inside which a substrate to be exposed is disposed, wherein an inner peripheral surface of the opening has a shape expanding toward a lower surface at least partly, inserting the substrate to be exposed having an external diameter smaller than the minimum internal diameter of the opening from above into the inside of the opening of the substrate holding member so as to dispose the substrate to be exposed on the substrate stage and allowing an immersion area interposed between an end part of projection optics and the substrate to be exposed to move relatively to the substrate to be exposed and simultaneously, exposing emission areas of the substrate to be exposed covered with the immersion area.

### BRIEF DESCRIPTION OF THE DRAWING

FIG. 1 is an explanatory view schematically showing a structure of an immersion type exposure device according to a first Example;

FIG. 2A is a plan view schematically showing a state that a wafer is disposed inside an opening of a water-repellent plate;

FIG. 2B is a cross-sectional view taken along the line A-A in FIG. 2A;

FIG. 3 is an explanatory view schematically showing a state of an interface of a liquid immersion in a gap between the wafer and the water-repellent plate;

FIG. 4 is a graph schematically showing a relationship between force P acting on the interface of the liquid immersion and slope θ of the inner peripheral surface of the water-repellent plate;

FIG. 5 is an explanatory view schematically showing a state of the interface of the liquid immersion in the gap between the wafer and the water-repellent plate in Comparative Example;

FIG. 6 is a graph schematically showing a relationship between the number of wafer and focus position in Comparative Example;

FIG. 7 is a graph schematically showing a temperature change of the immersion area during exposing a single wafer in Comparative Example;

FIG. 8 is an explanatory view schematically showing a cross-sectional shape of the inner peripheral surface of the water-repellent plate according to a second Example;

FIG. 9 is a graph schematically showing a relationship between a position z of the interface of the liquid immersion and the force P acting on the interface;

FIG. 10 is an explanatory view schematically showing a cross-sectional shape of the inner peripheral surface of the water-repellent plate according to a third Example; and

FIGS. 11A to 11F are explanatory views schematically showing variations of the inner peripheral surface of the water-repellent plate.

### DETAILED DESCRIPTION

### First Example

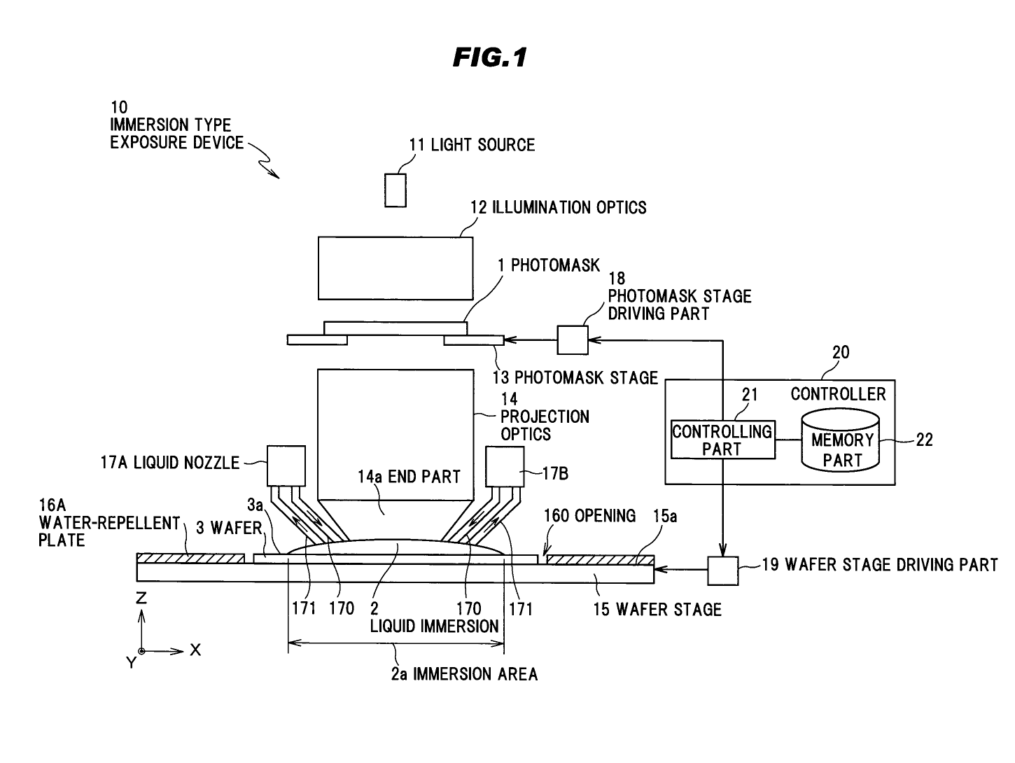

FIG. 1 is an explanatory view schematically showing a structure of an immersion type exposure device according to a first Example. Further, in FIG. 1, X, Y and Z show directions perpendicular to each other.

As shown in FIG. 1, the immersion type exposure device 10 includes a light source 11 for emitting an exposure light, an illumination optics 12 for illuminating a photomask 1 by the exposure light from the light source 11, a photomask stage on which the photomask 1 is disposed, a projection optics 14 for projecting the exposure light transmitting through the photomask 1 on the wafer as a substrate to be exposed via an immersion area 2a, a wafer stage 15 as a substrate stage on which the wafer 3 is disposed, a water-repellent plate 16A as a substrate holding member for holding the wafer 3, and liquid nozzles 17A, 17B for feeding a liquid immersion 2 to the immersion area 2a via feeding pipes 170 and recovering the liquid immersion 2 via recovering pipes 171.

The photomask 1 is obtained, for example, by forming a shielding film made of metal such as chromium on a transparent substrate made of silica glass or the like, and forming a mask pattern in the shielding film.

As the liquid immersion 2, generally, pure water is used, but an organic solvent or the like can be also used.

The wafer 3 can be constructed from the other substrate to be exposed such as a glass substrate. The upper surface 3a of the wafer 3 is coated with photoresist. Further, a resist protection film can be formed on the photoresist.

As the exposure light emitted from the light source 11, for example, emission lines (g rays, h rays, i rays) emitted from a mercury lamp, deep-ultraviolet light (DUV light) such as KrF excimer laser light (wavelength: 248 nm), ArF excimer laser light (wavelength: 193 nm) or the like can be used. In Examples, ArF excimer laser light is used.

The Photomask 1 is disposed on the upper surface of the photomask stage 13 by electrostatic adsorption or the like. The photomask stage 13 is formed so as to allow the Photomask 1 to be movable in X and Y directions. In addition, the photomask stage 13 is connected to a photomask stage driving part 18 for allowing the Photomask 1 to move in X and Y directions.

The water-repellent plate 16A has an opening 160 formed in a circle shape, an outline formed in a rectangle shape and a thickness almost equal to the wafer 3. In Example, the water-repellent plate 16A having a thickness of 800 μm is used. The water-repellent plate 16A can be formed of ceramics, glass, silicon or the like, a treatment for providing water repellent property (water-repellent treatment) is applied to the surface thereof so as to have a contact angle (for example, not less than 80 degrees) to the liquid immersion 2 larger than the wafer 3. In Example, the water-repellent plate 16A is formed of ceramics and a fluorine based coating is applied to the surface thereof. Further, in accordance with the contact angle to the liquid immersion 2, the substrate holding member whose surface is not subjected to the water-repellent treatment can be also used. And, the opening 160 of the water-repellent plate 16A is not limited to be circular, but can have a shape that corresponds to the wafer contour shape. Also, the outline of the water-repellent plate 16A is not limited to be rectangular, but can also have a circular shape or the like.

The water-repellent plate 16A is disposed on the upper surface 15a of the wafer stage 15, and the wafer 3 is inserted into and disposed on the inside of the opening 160 of the water-repellent plate 16A so as to be fixed by vacuum contact or the like. The wafer stage 15 is formed so as to allow the wafer 3 to be movable in X and Y directions. In addition, the wafer stage 15 is connected to a wafer stage driving part 19 for allowing the wafer 3 to move in X and Y directions.

The controller 20 includes a controlling part 21 formed so as to have a CPU, an interface circuit and the like, and a memory part 22 such as ROM, RAM, HDD for storing programs of the CPU or data. The CPU of the controlling part 21 controls the photomask stage driving part 18 and the wafer stage driving part 19 in accordance to programs to allow the Photomask 1 and the wafer 3 to move in synchronization in X and Y directions so that the exposure light can scan on the wafer 3.

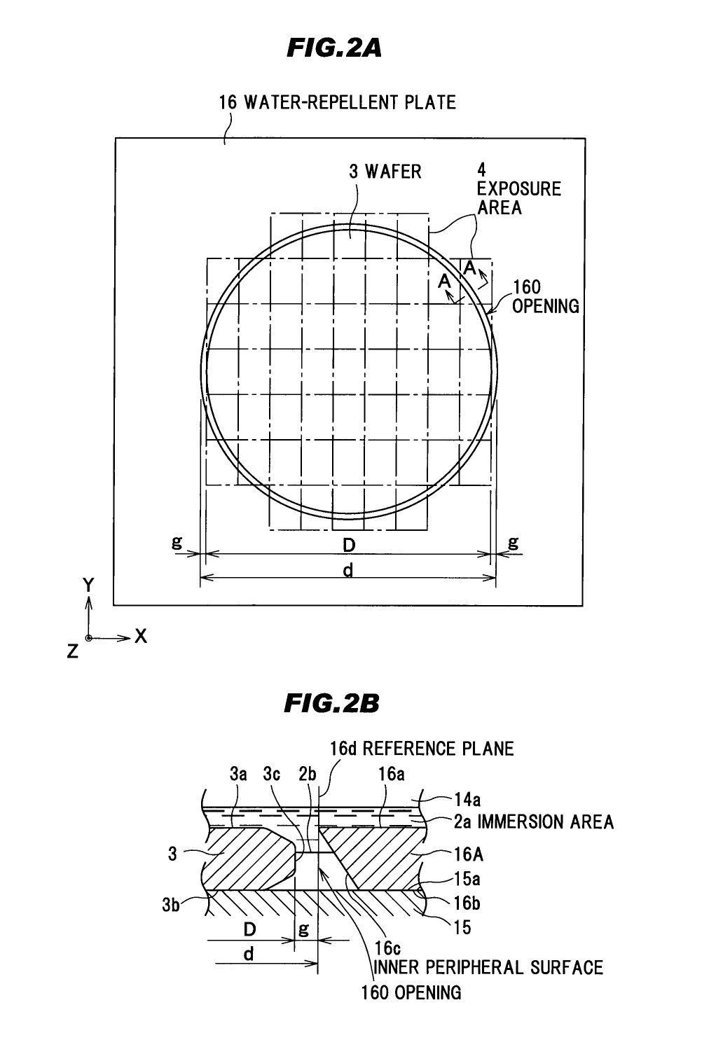

FIG. 2A is a plan view schematically showing a state that a wafer is disposed inside an opening of a water-repellent plate and FIG. 2B is a cross-sectional view taken along the line A-A in FIG. 2A.

As shown in FIG. 2B, in the water-repellent plate 16A, a minimum internal diameter d of the opening 160 is lager than a diameter of a space in which the wafer 3 on the wafer stage 15 is disposed (namely, an external diameter D of the wafer 3), and a gap g (=x1) of almost several hundreds μm in length exists between the opening 160 and the wafer 3.

A plurality of exposure areas (emission areas) 4 to be exposed by the exposure light transmitting through the mask pattern are located in a region including the wafer 3. When each of the exposure areas 4 is sequentially exposed by the exposure light, the immersion area 2a also moves on the wafer 3, consequently, when the exposure area 4 located at end portion is exposed, the immersion area 2a is located between the wafer 3 and the water-repellent plate 16A, therefore, it is necessary that the liquid immersion 2 is prevented from leaking from the gap g between the wafer 3 and the water-repellent plate 16A. In Example, a cross-sectional shape of the inner peripheral surface 16c of the opening 160 of the water-repellent plate 16A is formed so as to be a specific shape, so that the liquid immersion 2 can be prevented from leaking.

As shown in FIG. 2B, the inner peripheral surface 16c of the water-repellent plate 16A has a shape expanding toward a lower surface 16b at least partly. Here, the term “expanding shape” means a shape that has the internal diameter becoming larger in a direction toward the lower surface 16b from the upper surface 16a, or a shape that gets away from a reference plane 16d having a diameter (minimum internal diameter) d and being perpendicular to the upper surface 16a, in a direction toward the lower surface 16b from the upper surface 16a. The expanding shape of the inner peripheral surface 16c is a shape that when the liquid immersion 2 on the wafer 3 is introduced into a gap g between the wafer 3 disposed on the wafer stage 15 and the inner peripheral surface 16c of the opening 160 of the water-repellent plate 16A, acts so as to push up the interface of the liquid immersion 2 introduced into the gap g by resultant force of surface tensions that the liquid immersion 2a acts on an outer peripheral surface of the wafer 3 and the inner peripheral surface 16c of the opening 160 respectively. In the first Example, the inner peripheral surface 16c is constructed from a surface linearly inclined on a sectional view.

Further, in FIG. 2B, a referential mark “3b” shows a lower surface of the wafer 3. The wafer 3 having a cross-sectional shape of edge face of the outer peripheral surface 3c formed in a trapezoidal shape will be explained, but it can also have the other shapes such as a semicircular shape.

### (Cross-Sectional Shape of Inner Peripheral Surface of Water-Repellent Plate)

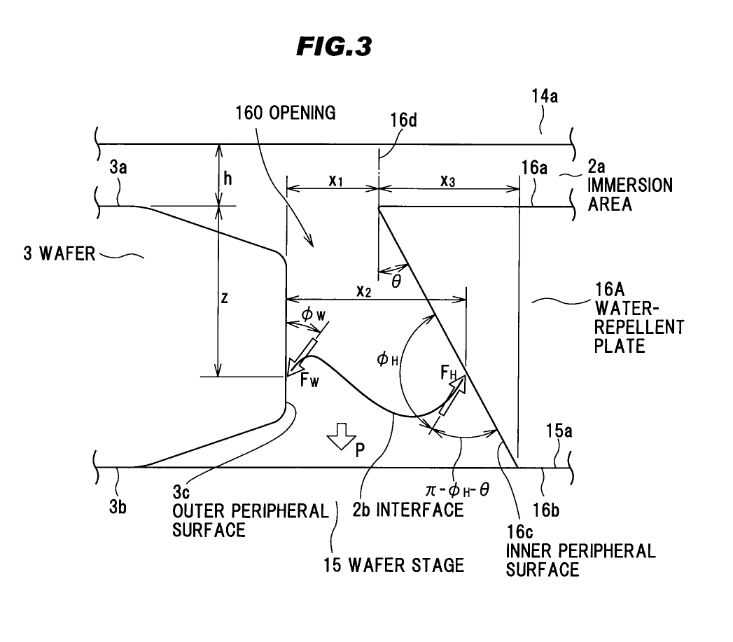

FIG. 3 is an explanatory view schematically showing a state of an interface of the liquid immersion 2 in the gap g between the wafer 3 and the water-repellent plate 16A. Further, in FIG. 3, a photoresist on the wafer 3 is not shown. A referential mark “h” in FIG. 3 shows a distance between the end part 14a of the projection optics 14 and the wafer 3. A referential mark “2b” in FIG. 3 shows a calculation result of interface position of the liquid immersion 2 in case that the wafer stage 15 moves at a speed of 500 mm/sec to the immersion area 2a. A force P acting on the reference plane 16d in a vertical direction thereof when surface tensions F_{W}, F_{H} of the liquid immersion 2 acting on the outer peripheral surface 3c of the wafer 3 and the inner peripheral surface 16c of the water-repellent plate 16A are combined, can be represented by the following formula (1).

P={σ cos (Φ_{W})−σ cos (π−Φ_{H}−θ)}/(x₁+z tan (θ)) (1)

Here, σ shows a coefficient determined by kind of liquid immersion 2, Φ_{W} shows a contact angle of the liquid immersion 2 at the outer peripheral surface 3c of the wafer 3, Φ_{H} shows a contact angle of the liquid immersion 2 at the inner peripheral surface 16c of the water-repellent plate 16A, θ shows a slope of the inner peripheral surface 16c of the water-repellent plate 16A to the reference plane 16d, x1 shows a minimum distance between the wafer 3 and the water-repellent plate 16A, and z shows a distance from the upper surface 3a of the wafer 3 (the water-repellent plate 16A) to the interface 2b of the liquid immersion 2.

In the formula (1), if P is positive, P acts on the interface 2b downward, and if P is negative, P acts on the interface 2b upward. Consequently, in order to prevent the liquid immersion 2 from leaking from the gap g between the wafer 3 and the water-repellent plate 16A, P is needed to be negative. The condition expression is shown in the following formula (2).

cos (Φ_{W})<cos (π−Φ_{H}−θ) (2)

When the above-mentioned formula (2) is satisfied, the interface 2b of the liquid immersion 2 is urged to be pushed up, so that the liquid immersion 2 can be prevented from leaking.

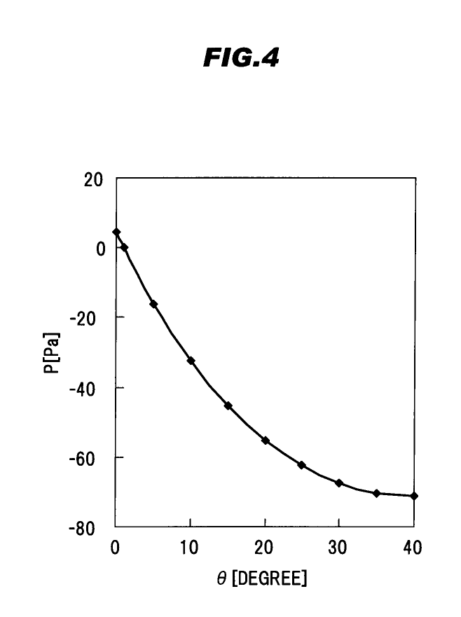

FIG. 4 is a graph schematically showing a relationship between force P acting on the interface 2b of the liquid immersion 2 and slope θ of the inner peripheral surface 16c of the water-repellent plate 16A. FIG. 4 shows a calculation result when σ=0.0727 N/m, Φ_{W}=69 degrees, Φ_{H}=110 degrees, x₁=266 μm and Z=300 μm in the formula (1). From FIG. 4, it is known that when the slope θ of the inner peripheral surface 16c of the water-repellent plate 16A becomes large, P becomes negative, so that the force P capable of pushing up the interface 2b of the liquid immersion 2 becomes large.

### (Exposure Operation)

Next, an operation of the immersion type exposure device 10 will be explained. First, the water-repellent plate 16A is disposed on the wafer stage 15, and the wafer 3 coated with the photoresist is inserted from above into the inside of the opening 160 of the water-repellent plate 16A so as to be disposed on the substrate stage 15. Next, the liquid immersion 2 is fed from the liquid nozzles 17A, 17B so that the immersion area 2a is interposed between the end part 14a of the projection optics 14 and the wafer 3. Next, the immersion area is relatively moved to the wafer 3 and simultaneously, the emission areas 4 of the wafer 3 covered with the immersion area 2a are exposed. Namely, the CPU of the controlling part 21 controls the photomask stage driving part 18 and the wafer stage driving part 19 in accordance to programs to allow the Photomask 1 and the wafer 3 to move in synchronization in X and Y directions so that the exposure light can scan on the wafer 3. The emission areas 4 on the wafer 3 are sequentially exposed so that the mask pattern is projected on the whole surface of the wafer 3. After that, a semiconductor device or the like is fabricated by passing through well-known processes including development, etching, resist separation and the like.

### Comparative Example

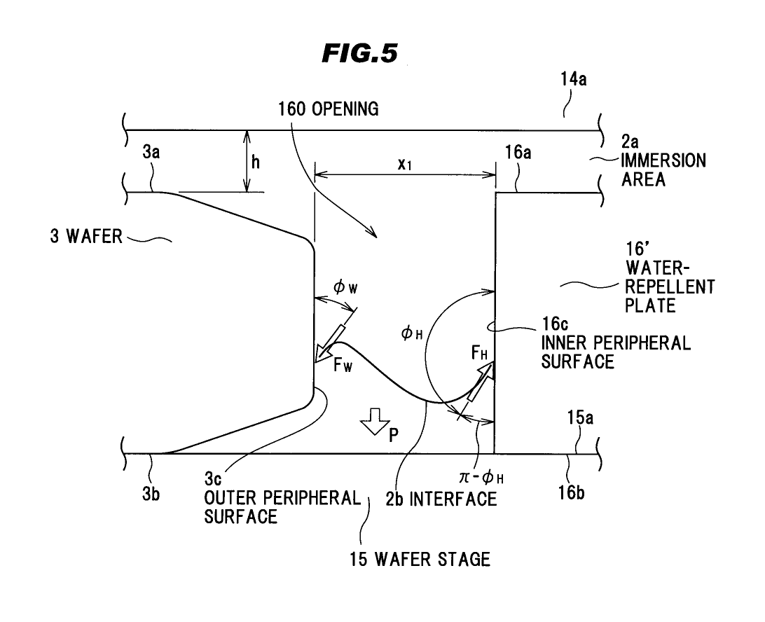

FIGS. 5 to 7 show Comparative Example. In Comparative Example, the inner peripheral surface 16c of the water-repellent plate 16′ is formed to be vertical.

FIG. 5 is an explanatory view schematically showing a state of the interface of the liquid immersion 2 in the gap between the wafer 3 and the water-repellent plate 16′ in Comparative Example. Further, in FIG. 5, the photoresist on the wafer 3 is not shown. In Comparative Example, it is known that when θ=0 degree in FIG. 4, the force P becomes positive (P=4.47 Pa), consequently, the force P acts so as to push down the interface 2b of the liquid immersion 2 and the liquid immersion 2 leaks from the gap.

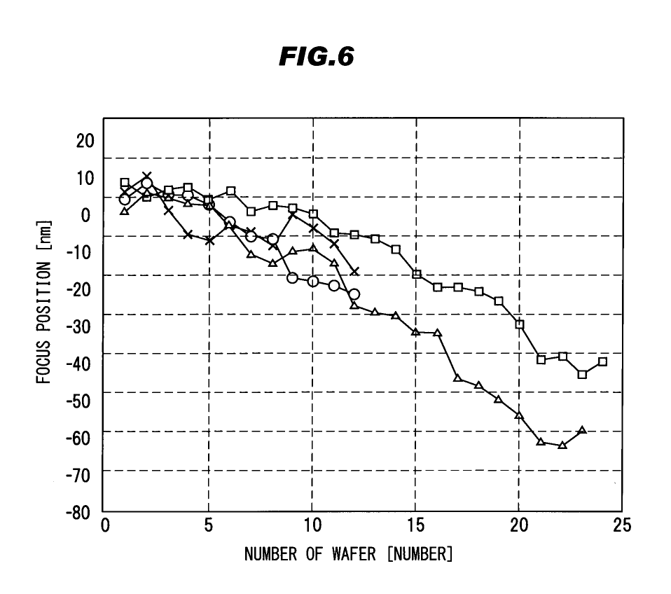

FIG. 6 is a graph schematically showing a relationship between the number of wafer and focus position in Comparative Example. In FIG. 6, marks of tetragon, circle, triangle, and cross show measurement results of the focus position in case that twelve or twenty four wafers are continuously exposed in different days in Comparative Example. When the focus position is minus, it shows that the focus position is displaced downward. From the FIG. 6, it is known that in Comparative Example, in accordance with increase in the number of the wafer, the focus position deteriorates.

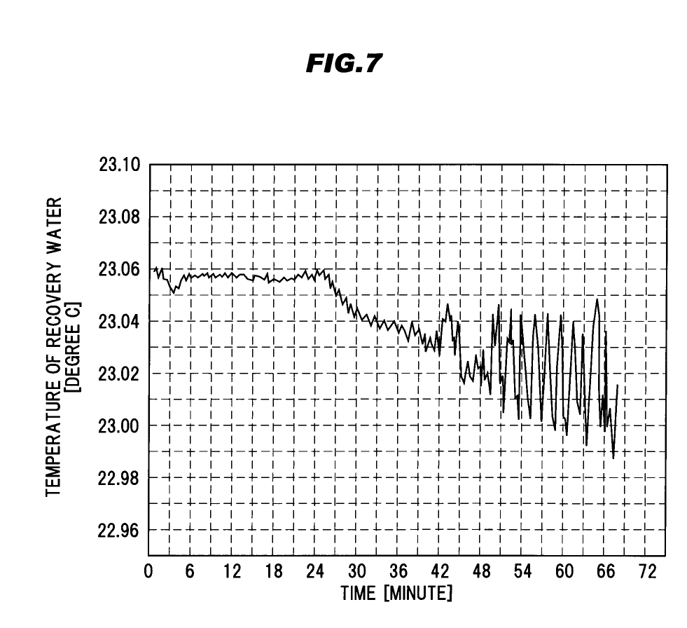

FIG. 7 is a graph schematically showing a temperature change of the immersion area 2a during exposing a single wafer 3 in Comparative Example. Instead of measuring the temperature of the immersion area 2a, a temperature of recovered water which was obtained by recovering the liquid immersion 2 at an outlet of the recovering pipes 171 of the liquid nozzles 17A, 17B was measured by a temperature sensor. From FIG. 7, it is known that when 27 minutes pass from the start of the exposure, the temperature of the recovered water drops not less than 0.02 degrees C. In accordance with the temperature change of the immersion area 2a, focus change at the exposure is caused.

### (Advantages of First Example)

According to the first Example, the liquid immersion 2 can be prevented from leaking from the gap g between the wafer 3 and the water-repellent plate 16A. As a result, the temperature of the immersion area 2a hardly changes, and even if the wafer 3 is continuously exposed as shown in Comparative Example, the focus position is not displaced, so that stabilization of exposure accuracy can be enhanced. Also, the minimum internal diameter d of the water-repellent plate 16A is larger than the diameter of the wafer 3 and the water-repellent plate 16A does not cover the wafer 3 so that the wafer can be easily removed without moving the water-repellent plate 16A after completion of the exposure to the wafer 3. Consequently, the sequential exposure process to the wafer 3 can be more promptly and easily carried out. cl Second Example

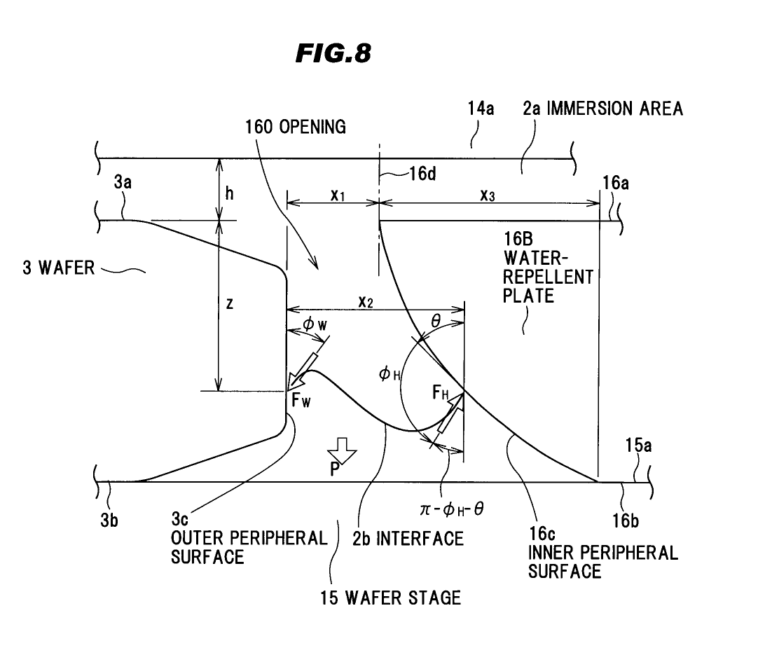

FIG. 8 is an explanatory view schematically showing a cross-sectional shape of the inner peripheral surface of the water-repellent plate according to the second Example. Further, in FIG. 8, a photoresist on the wafer 3 is not shown.

The water-repellent plate 16B according to the second Example is formed so as to have an inner peripheral surface 16c constructed from a curved surface bulging toward the opening 160, and the other construction of the immersion type exposure device 10 is similar to the first Example.

A referential mark “2b” in FIG. 3 shows a calculation result of interface position of the liquid immersion 2 in case that the wafer stage 15 moves at a speed of 500 mm/sec to the immersion area 2a. A force P acting on the reference plane 16d in a vertical direction thereof when surface tensions FW, FH acting on the outer peripheral surface 3c of the wafer 3 and the inner peripheral surface 16c of the water-repellent plate 16B are combined, can be represented by the following formula (3).

P={σ cos (Φ_{W})−σ cos (π−Φ_{H}−θ(z))}/(x₂(z)) (3)

Here, σ shows a coefficient determined by kind of liquid immersion 2, Φ_{W} shows a contact angle of the liquid immersion 2 at the outer peripheral surface 3c of the wafer 3, Φ_{H} shows a contact angle of the liquid immersion 2 at the inner peripheral surface 16c of the water-repellent plate 16B, θ(z) shows a slope of the inner peripheral surface 16c of the water-repellent plate 16B to the reference plane 16d at the Z position, x₂ shows a horizontal length at the Z position, and z shows a distance from the upper surface 3a of the wafer 3 (the water-repellent plate 16B) to the interface 2b of the liquid immersion 2.

The shape of the inner peripheral surface 16c of the water-repellent plate 16B can be also described as “the lager the Z is, the lager the θ(z) is”. In the above-mentioned formula (3), if P is positive, P acts on the interface 2b downward, and if P is negative, P acts on the interface 2b upward. Consequently, in order to prevent the liquid immersion 2 from leaking from the gap g between the wafer 3 and the water-repellent plate 16B, P is needed to be negative. The condition expression is shown in the following formula (4).

cos (Φ_{W})<cos (π−Φ_{H}−θ(z)) (4)

When the above-mentioned formula (4) is satisfied, the interface 2b of the liquid immersion 2 is urged to be pushed up, so that the liquid immersion 2 can be prevented from leaking.

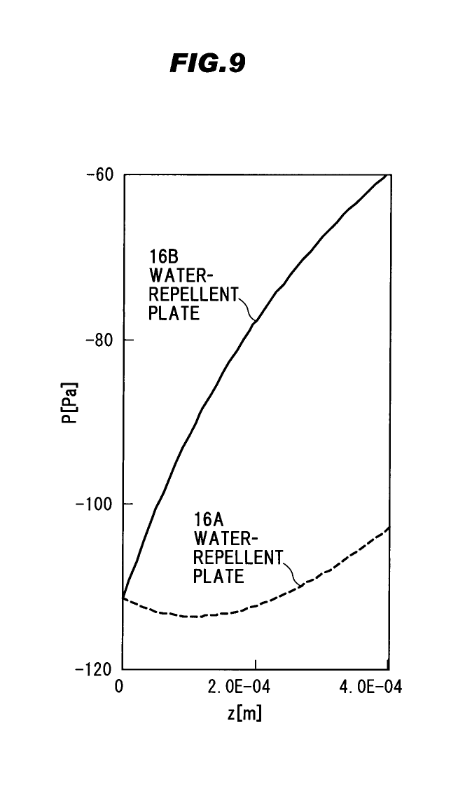

FIG. 9 is a graph schematically showing a relationship between the position z of the interface 2b of the liquid immersion 2 and the force P acting on the interface. FIG. 9 shows a calculation result when σ=0.0727 N/m, Φ_{W}=69 degrees, Φ_{H}=110 degrees, and x₁=266 μm in the formula (1) and (3) corresponding to the water-repellent plates 16A,16B shown in FIG. 3 and 8. From FIG. 9, it is known that in case of the water-repellent plate 16B, in accordance with increase in the z, the force P capable of pushing up the interface 2b of the liquid immersion 2 becomes large, on the other hand, in case of the water-repellent plate 16A shown in FIG. 3, the force P capable of pushing up does not particularly become large, in comparison with the water-repellent plate 16B shown in FIG. 8 even if the Z becomes large.

According to the second Example, the interface 2b of the liquid immersion 2 can be held at the side of the lower surface 16b of the water-repellent plate 16B, so that the liquid immersion 2 can be prevented from leaking. Also, similarly to the first Example, the sequential exposure process to the wafer 3 can be more promptly and easily carried out.

### Third Example

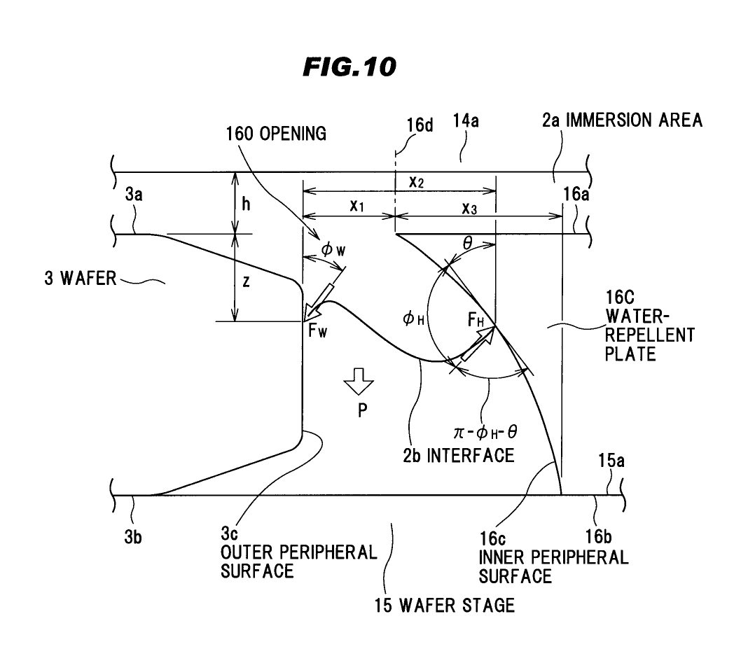

FIG. 10 is an explanatory view schematically showing a cross-sectional shape of the inner peripheral surface of the water-repellent plate according to the third Example. Further, in FIG. 10, a photoresist on the wafer 3 is not shown.

The water-repellent plate 16C according to the third Example is formed so as to have an inner peripheral surface 16c constructed from a curved surface bulging oppositely to the opening 160, and the other construction of the immersion type exposure device 10 is similar to the first Example. The shape of the inner peripheral surface 16c of the water-repellent plate 16C can be also described as “the smaller the Z is, the lager the θ(z) is”. And, a width x₃ of the inner peripheral surface 16c can be maintained small so that the device configuration can be formed to be compact.

According to the third Example, the interface 2b of the liquid immersion 2 can be held at the side of the upper surface 16a of the water-repellent plate 16C, so that the liquid immersion 2 can be prevented from leaking. Also, similarly to the first Example, the sequential exposure process to the wafer 3 can be more promptly and easily carried out.

### (Modification of Inner Peripheral Surface of Water-Repellent Plate)

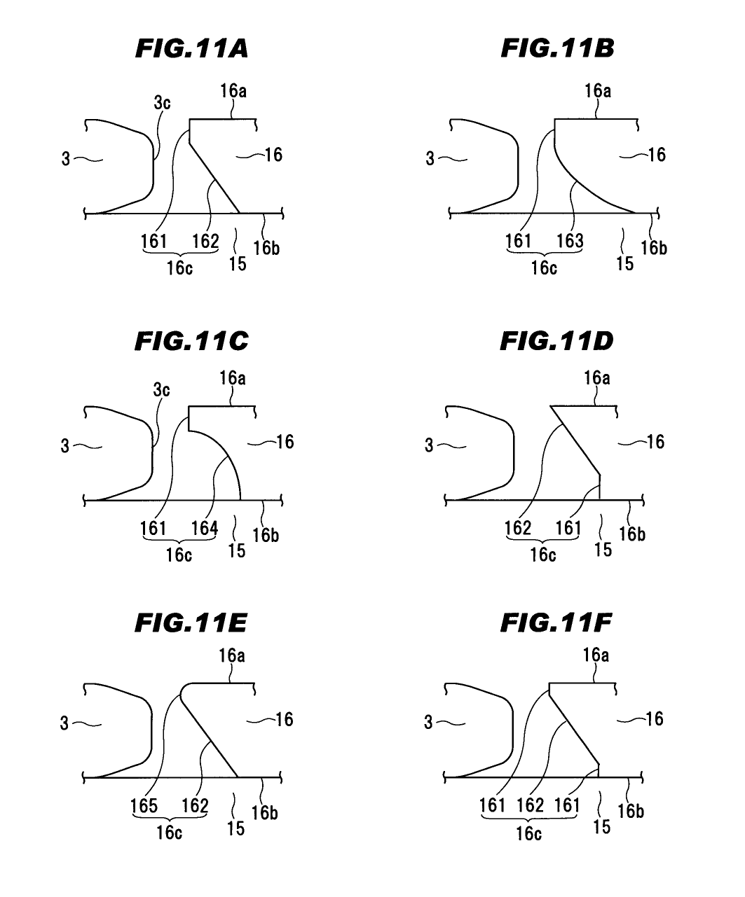

FIGS. 11A to 11F are explanatory views schematically showing variations of the inner peripheral surface of the water-repellent plate. The shape of the inner peripheral surface 16c of the water-repellent plate 16 can be constructed from a combination of at least two surfaces selected from the group consisting of the surface linearly inclined on a sectional view as shown in FIG. 3, the surface formed to be vertical as shown in FIG. 5, the curved surface bulging toward the opening as shown in FIG. 8, and the curved surface bulging toward an opposite side to the opening as shown in FIG. 10. For example, the shape of the inner peripheral surface 16c of the water-repellent plate 16 can be formed so as to have shapes shown in FIGS. 11A to 11F.

FIG. 11A shows a shape that has a vertical surface 161 disposed in the side of the upper surface 16a and a linearly inclined surface 162 disposed in the side of the lower surface 16b. FIG. 11B shows a shape that has the vertical surface 161 disposed in the side of the upper surface 16a and a bulging surface 163 toward the opening 160 disposed in the side of the lower surface 16b. FIG. 11C shows a shape that has the vertical surface 161 disposed in the side of the upper surface 16a and a bulging surface 164 opposite to the opening 160 disposed in the side of the lower surface 16b.

FIG. 11D shows a shape that has the linearly inclined surface 162 disposed in the side of the upper surface 16a and the vertical surface 161 disposed in the side of the lower surface 16b. Similarly to this, a shape can be also used that has the bulging surface 163 toward the opening 160 or the bulging surface 164 opposite to the opening 160 disposed in the side of the upper surface 16a and the vertical surface 161 disposed in the side of the lower surface 16b.

FIG. 11E shows a shape that has a semicircular surface 165 disposed in the side of the upper surface 16a and the linearly inclined surface 162 disposed in the side of the lower surface 16b. Similarly to this, a shape can be also used that has the semicircular surface 165 disposed in the side of the upper surface 16a and the bulging surface 163 toward the opening 160 or the bulging surface 164 opposite to the opening 160 disposed in the side of the lower surface 16b.

FIG. 11F shows a shape that has the respective vertical surfaces 161 disposed in the sides of the upper surface 16a and the lower surface 16b and the linearly inclined surface 162 disposed between both the surfaces 161. In this case, the vertical surface 161 disposed in the side of the upper surface 16a can be replaced with the semicircular surface 165 as shown in FIG. 11E. Also, the linearly inclined surface 162 can be replaced with the bulging surface 163 toward the opening 160 or the bulging surface 164 opposite to the opening 160.

Further, it should be noted that the present invention is not intended to be limited to the above-mentioned embodiments and modification, and the various kinds of changes thereof can be implemented by those skilled in the art without departing from the gist of the invention.

What is claimed is:

1. A substrate holding member, comprising:
an opening having a minimum internal diameter lager than a diameter of a space in which a substrate to be exposed on a substrate stage is disposed, wherein an inner peripheral surface of the opening has a shape expanding toward a lower surface at least partly.

2. The substrate holding member according to claim 1, wherein the expanding shape is a shape that has the internal diameter becoming larger in a direction toward the lower surface from the upper surface.

3. The substrate holding member according to claim 1, wherein the expanding shape is a shape that gets away from a reference plane having the minimum internal diameter and being perpendicular to the upper surface, in a direction toward the lower surface from the upper surface.

4. The substrate holding member according to claim 1, wherein the expanding shape is a shape that when a liquid immersion on the substrate to be exposed is introduced into a gap between the substrate to be exposed disposed on a substrate stage and the inner peripheral surface of the opening, acts so as to push up an interface of the liquid immersion introduced into the gap by resultant force of surface tensions that the liquid immersion acts on an outer peripheral surface of the substrate to be exposed and the inner peripheral surface of the opening respectively.

5. The substrate holding member according to claim 1, wherein the expanding shape is constructed from a curved surface shown as an inclined line on a sectional view.

6. The substrate holding member according to claim 1, wherein the expanding shape is constructed from a curved surface bulging toward the opening.

7. The substrate holding member according to claim 1, wherein the expanding shape is constructed from a curved surface bulging toward an opposite side to the opening.

8. The substrate holding member according to claim 1, wherein the expanding shape is constructed from a combination of at least two surfaces selected from the group consisting of the surface linearly inclined on a sectional view, the curved surface bulging toward the opening, and the curved surface bulging toward an opposite side to the opening.

9. The substrate holding member according to claim 1, wherein the substrate holding member has almost the same thickness as the substrate to be exposed.

10. The substrate holding member according to claim 1, wherein the substrate holding member has a surface to which water-repellent treatment is applied.

11. The substrate holding member according to claim 10, wherein the surface has a contact angle of not less than 80 degrees.

12. The substrate holding member according to claim 1, wherein the substrate holding member is formed of ceramics and has a surface which is coated with fluorine based coating.

13. An immersion type exposure device, comprising:
a substrate holding member having an opening inside which a substrate to be exposed is disposed, wherein an inner peripheral surface of the opening has a shape expanding toward a lower surface at least partly;
a substrate stage on which the substrate holding member is disposed; and
a controller for allowing an immersion area interposed between an end part of projection optics and the substrate to be exposed to move relatively to the substrate to be exposed and simultaneously, exposing emission areas of the substrate to be exposed covered with the immersion area.

14. The immersion type exposure device according to claim 13, wherein the expanding shape is constructed from a surface linearly inclined on a sectional view.

15. The immersion type exposure device according to claim 13, wherein the expanding shape is constructed from a curved surface bulging toward the opening.

16. The immersion type exposure device according to claim 13, wherein the expanding shape is constructed from a curved surface bulging toward an opposite side to the opening.

17. A method of fabricating a semiconductor device, comprising:
disposing a substrate holding member on a substrate stage, the substrate holding member having an opening inside which a substrate to be exposed is disposed, wherein an inner peripheral surface of the opening has a shape expanding toward a lower surface at least partly;
inserting the substrate to be exposed having an external diameter smaller than the minimum internal diameter of the opening from above into the inside of the opening of the substrate holding member so as to dispose the substrate to be exposed on the substrate stage; and
allowing an immersion area interposed between an end part of projection optics and the substrate to be exposed to move relatively to the substrate to be exposed and simultaneously, exposing emission areas of the substrate to be exposed covered with the immersion area.

18. The method of fabricating a semiconductor device according to claim 17, wherein the expanding shape is constructed from a surface linearly inclined on a sectional view.

19. The method of fabricating a semiconductor device according to claim 17, wherein the expanding shape is constructed from a curved surface bulging toward the opening.

20. The method of fabricating a semiconductor device according to claim 17, wherein the expanding shape is constructed from a curved surface bulging opposite to the opening.
